(19) United States
(12) Patent Application Publication
(10) Pub. No.: US 2023/0197413 A1
(43) Pub. Date: Jun. 22, 2023

(54) SEMICONDUCTOR PROCESS METHOD AND MULTI-CHAMBER APPARATUS THEREWITH

(71) Applicant: HANGZHOU FULLSEMI SEMICONDUCTOR CO., LTD., Hangzhou (CN)

(72) Inventors: Ke Han, Hangzhou (CN); Xinjia Qian, Hangzhou (CN); Qiong Sun, Hangzhou (CN)

(21) Appl. No.: 17/948,852

(22) Filed: Sep. 20, 2022

(30) Foreign Application Priority Data
Dec. 17, 2021 (CN) 202111553675.5

(51) Int. Cl. H01J 37/32

(52) U.S. Cl. CPC H01J 37/3244; H01J 37/32211; H01J 37/32816

(57) ABSTRACT

The present disclosure relates to a multi-chamber apparatus and a semiconductor process method which includes steps of applying a first chamber and a second chamber with a process gas and a radio frequency, so as to acquire a first time difference between a plot of the first initial RF applying versus time and a plot of gas flow versus time and a second time difference between a plot of the second initial RF applying versus time and the plot of gas flow versus time in advance, then executing calibration through the first time difference and the second time difference. Accordingly, a first radio frequency generating unit, a second radio frequency generating unit and a gas source unit of the multi-chamber apparatus are turned off simultaneously, such that quality of the first substrate deposited in the first chamber and the second substrate deposited in the second chamber are relatively uniform.

### FIELD OF THE DISCLOSURE

The present disclosure relates generally to a semiconductor process method and a multi-chamber process apparatus therewith, and more particularly, to a semiconductor process method capable of enhancing production rate as well as improving yield rate in a multi-chamber apparatus therewith.

### BACKGROUND

Plasma Enhanced Chemical Vapor Deposition (PECVD) technology is widely implemented in integrated circuit manufacturing industry. For examples, in deposition technology, increasing production efficiency, some of the manufacturing equipment applies an apparatus with a twin chamber to deposit two wafers simultaneously so as to improve the utilization rate of the machine, to improve the overall production efficiency, and to reduce the clean room space occupied by the machines. However, differences of uneven distribution of reactive gases between the two chambers, mechanical differences in heaters, asynchrony of two radio frequency (RF) generators in twin units, have resulted in different qualities of the wafers deposited by the two units of the chamber, generating the chamber mismatch problems. In particular, the asynchrony of the two RF generators, e.g., one of the two RF generators is turned off when the gas supply unit of the machine still supplies gas at least for the other unit, has mattered the most, because then tiny particles or bump defects occur easily on wafers.

### SUMMARY OF THE DISCLOSURE

To overcome the shortcomings existing in current technologies, including the single specification of the asynchrony of the two RF generators, e.g., one of the two RF generators is turned off when a gas supply unit of the machine still supplies gas, the present disclosure provides a semiconductor process method and a multi-chamber apparatus therewith.

According to an embodiment, a semiconductor process method adapted to a multi-chamber apparatus is disclosed. The multi-chamber apparatus includes a gas source unit, a first chamber, a second chamber, a first radio frequency (RF) generating unit and a second RF generating unit. The gas source unit is configured to communicate with the first chamber and the second chamber and to provide the first chamber and the second chamber with a process gas. The first RF generating unit is coupled to the first chamber, and the second RF generating unit is coupled to the second chamber. The semiconductor process method includes: generating a plot with a plot of gas flow versus time for the gas source unit which provides the process gas to the first chamber and the second chamber according to a gas flow parameter; generating a plot with a plot for the first initial RF power applied by the first RF generating unit into the first chamber versus time according to a first initial RF applying time parameter; generating a plot with a plot of the second initial RF power applied by the second RF generating unit into the second chamber versus time according to a second initial RF applying time parameter; computing a first time difference according to the plot of gas flow versus time and the plot of the first initial RF applying versus time; computing a second time difference according to the plot of gas flow versus time and the plot of the second initial RF applying versus time; deriving a first RF applying time calibration parameter according to the first initial RF applying time parameter and the first time difference, and the first RF generating unit applying the radio frequency power to the first chamber according to the first RF applying time calibration parameter; and deriving a second RF applying time calibration parameter according to the second initial RF applying time parameter and the second time difference, and the second RF generating unit applying the radio frequency power to the second chamber according to the second RF applying time calibration parameter.

According to another embodiment, the semiconductor process method further includes disposing a first substrate and a second substrate into the first chamber and the second chamber, respectively, before the gas source unit providing the process gas to the first chamber and the second chamber according to the gas flow parameter.

According to another embodiment, after disposing the first substrate and the second substrate into the first chamber and the second chamber, respectively, and before the gas source unit providing the process gas to the first chamber and the second chamber according to the gas flow parameter, the semiconductor process method further includes: providing a pre-process gas to the first chamber and the second chamber; after providing the pre-process gas to the first chamber and the second chamber, the first RF generating unit applying another radio frequency to the first chamber with according to another first initial RF applying time parameter, so as to react the pre-process gas with impurities on the first substrate; and after providing the pre-process gas to the first chamber and the second chamber, the second RF generating unit applying another radio frequency to the second chamber according to another second initial RF applying time parameter, so as to react the pre-process gas with impurities on the second substrate.

According to another embodiment, after the first RF generating unit applying the radio frequency power to the first chamber according to the first initial RF applying time parameter and after the second RF generating unit applying the radio frequency power to the second chamber according to the second initial RF applying time parameter, the semiconductor process method further includes discharging gas in the first chamber and gas in the second chamber.

According to another embodiment, the semiconductor process method further includes communicating the first chamber with the second chamber by a communicating channel; and measuring pressure in the first chamber and pressure in the second chamber by a pressure gauge.

The present disclosure provides a multi-chamber apparatus adapted to a semiconductor process method, including a gas source unit, a first chamber, a second chamber, a first radio frequency (RF) generating unit coupled to the first chamber, a second RF generating unit coupled to the second chamber and a processor unit. The gas source unit is communicated with the first chamber and the second chamber for providing a process gas to the first chamber and the second chamber. The first radio frequency (RF) generating unit is coupled to the first chamber. The second RF generating unit is coupled to the second chamber. The processor unit is coupled to the gas source unit, the first RF generating unit and a second RF generating unit. The processor unit is configured to control the gas source unit to provide the process gas to the first chamber and the second chamber according to a gas flow parameter, so as to generate a plot of gas flow versus time; control the first RF generating unit to apply a radio frequency to the first chamber according to a first initial RF applying time parameter, so as to generate a plot of the first initial RF applying versus time; control the second RF generating unit to apply the radio frequency to the second chamber according to a second initial RF applying time parameter, so as to generate a plot of the second initial RF applying versus time; compute a first time difference according to the plot of gas flow versus time and the plot of the first initial RF applying versus time; compute a second time difference according to the plot of gas flow versus time and the plot of the second initial RF applying versus time; derive a first RF applying time calibration parameter according to the first initial RF applying time parameter and the first time difference, and the first RF generating unit applying the radio frequency power to the first chamber according to the first RF applying time calibration parameter; and derive a second RF applying time calibration parameter according to the second initial RF applying time parameter and the second time difference, and the second RF generating unit applying the radio frequency power to the second chamber according to the second RF applying time calibration parameter.

According to another embodiment, the multi-chamber apparatus further includes a gas discharging unit. The gas discharging unit is communicated with the first chamber and the second chamber.

According to another embodiment, the multi-chamber apparatus further includes a communicating channel and a pressure gauge. The communicating channel is configured for communicating the first chamber with the second chamber. The pressure gauge is for measuring pressure in the first chamber and pressure in the second chamber.

In summary, the present disclosure relates to the multi-chamber apparatus and the semiconductor process method which includes steps of applying the process gas and the radio frequency to the first chamber and the second chamber, so as to compute the first time difference between the plot of the first initial RF applying versus time and the plot of gas flow versus time and the second time difference between the plot of the second initial RF applying versus time and the plot of gas flow versus time in advance, then executing calibration through the first time difference and the second time difference. Accordingly, the first radio frequency generating unit, the second radio frequency generating unit and the gas source unit of the multi-chamber apparatus are turned off simultaneously, such that quality of the first substrate deposited in the first chamber and the second substrate deposited in the second chamber are relatively uniform.

### BRIEF DESCRIPTION OF THE DRAWINGS

The present disclosure will be best understood by referring to the following detailed description of the embodiments in conjunction with the accompanying illustrative drawings.

FIG. 1 is a schematic diagram of a multi-chamber apparatus according to an embodiment of the present disclosure;

FIG. 2 is a flow chart of a semiconductor process method according to an embodiment of the present disclosure;

FIG. 3 shows an example of a user interface table in an initial input status according to an embodiment of the present disclosure;

FIG. 4 is a plot diagram of gas flow versus time, showing a plot of the applied first initial RF power versus time and a plot of the applied second initial RF power versus time according to an embodiment of the present disclosure;

FIG. 5 shows an example of a user interface table in a calibration input status according to an embodiment of the present disclosure;

FIG. 6 is plot a diagram of plotgas flow versus time, showing a plot of the applied first calibration RF power versus time and a plot of the applied second calibration RF power versus time according to an embodiment of the present disclosure; and

FIG. 7 is a schematic block diagram of various functional parts of a multi-chamber apparatus according to an embodiment of the present disclosure.

### DETAILED DESCRIPTION

To facilitate the understanding of those skilled in the art, the present disclosure will be further described below with embodiments and accompanying drawings. The contents mentioned in the embodiments are not intended to limit the present disclosure. In addition, for the convenience of illustration, the components shown in the drawings of the present disclosure are not drawn in equal scale with the actual amount, shape, and size, and the detailed scale can be adjusted according to design requirements.

The directional terms mentioned in the following embodiments, such as on, below, left, right, front or rear, etc., are only referring to the directions of the attached drawings. Accordingly, the directional terms used are illustrative and not limiting of the present disclosure.

The term “coupling” mentioned in the following embodiments includes direct or indirect connection between a mechanical component and an electronic component or between a mechanical component and another mechanical component, as well as between an electronic component and another electronic component or electronic components on a mechanical component A communication connection is formed between the component and another electronic component on another mechanical component by means of signal transmission.

Although the terms first, second, third . . . may be used to describe various components, the components are not limited by these terms. This term is only used to distinguish a single component from other components in the specification. The same terms may not be used in the claim, but replaced by first, second, third . . . according to the order of component declaration in the claim. Therefore, in the following description, the first component may be the second component in the claim.

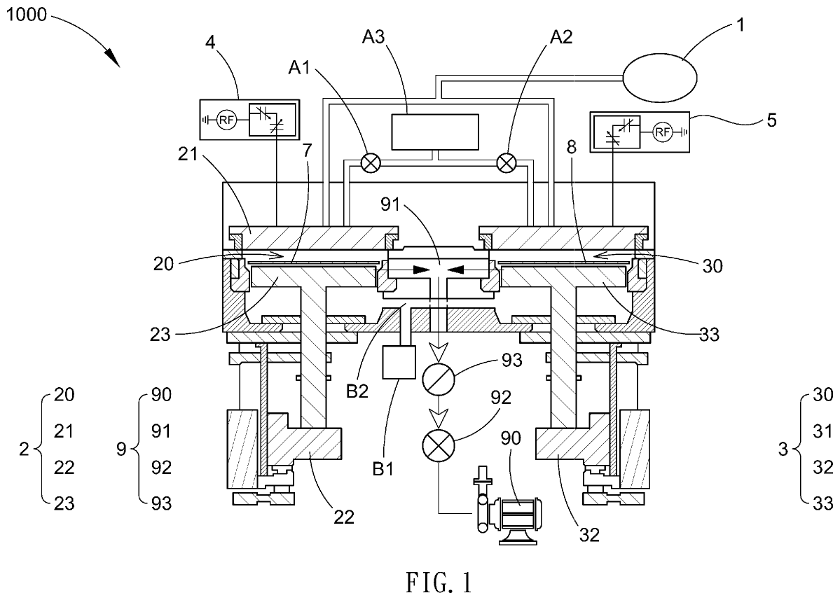

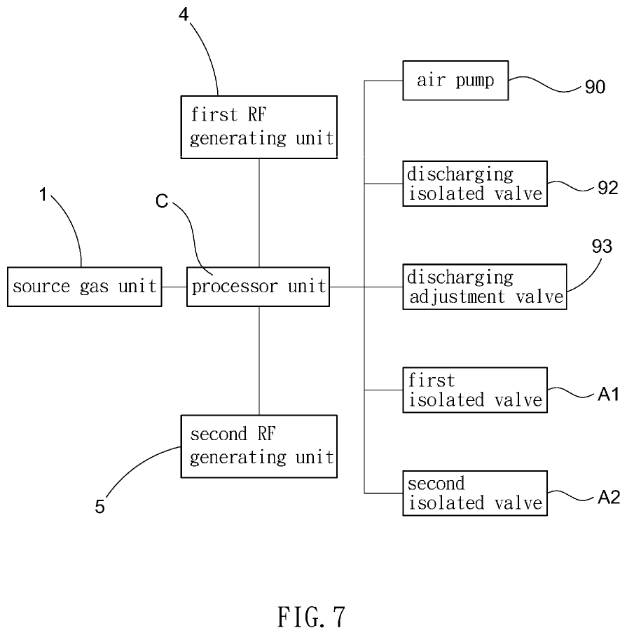

Please refer to FIG. 1 and FIG. 7. FIG. 1 is a schematic diagram of a multi-chamber apparatus 1000 according to an embodiment of the present disclosure. FIG. 7 is a schematic block diagram of various functional parts of the multi-chamber apparatus 1000 according to the embodiment of the present disclosure. The multi-chamber apparatus 1000 includes a gas source unit 1, a first chamber 2, a second chamber 3, a first radio frequency (RF) power generating unit 4, a second RF generating unit 5 and a processor unit C. The gas source unit 1 is communicated with the first chamber 2 and the second chamber 3 and for providing a process gas to the first chamber 2 and the second chamber 3. In the embodiment, the gas source unit 1 may be a semiconductor gas supply system which includes a hydrogen purifier, a nitrogen purifiers, an ammonia purifiers, a gas cylinder cabinets, a gas mixing equipment or combinations thereof. The process gas may be hydrogen, nitrogen, ammonia, inert gases or combinations thereof, depending on practical demands. In the embodiment, each of the first chamber 2 and the second chamber 3 may include a first chamber room 20 and a second chamber room 30. The first chamber room 20 and the second chamber room 30 are both hollow chamber. The gas source unit 1 is communicated with the first chamber room 20 of the first chamber 2 and the second chamber room 30 of the second chamber 3.

The first RF generating unit 4 is coupled to the first chamber 2. The second RF generating unit 5 is coupled to the second chamber 3. The processor unit C is coupled to the gas source unit 1, the first RF generating unit 4 and the second RF generating unit 5. In the embodiment, each of the first RF generating unit 4 and the second RF generating unit 5 is a radio frequency power generator with frequency band between 10 MHz and 15 MHz. The processor unit C may be a Programmable Logic Controller (PLC) or a combination of a Central Processing Unit (CPU) and the PLC.

In one embodiment, the first chamber 2 may include a first flow plate 21, a first heat source 22 and a first heating plate 23. The first flow plate 21, the first heat source 22 and the first heating plate 23 are disposed in the first chamber room 20. The first flow plate 21 has a plurality of flow penetrating holes (not shown in figures) and the plurality of flow penetrating holes are communicated with the gas source unit 1 and the first chamber room 20, such that the gas source unit 1 provides the process gas to the first chamber room 20 through the plurality of flow penetrating holes on the first flow plate 21. The first heat source 22 is for providing heat conducted to the first chamber room 20 through the first heating plate 23, so as to heat the first chamber room 20 and/or keep temperature of the first chamber room 20, which satisfies demands of the semiconductor process.

Similarly, the second chamber 3 may include a second flow plate 31, a second heat source 32 and a second heating plate 33. The second flow plate 31, the second heat source 32 and the second heating plate 33 are disposed in the second chamber room 30. The second flow plate 31 has a plurality of flow penetrating holes (not shown in figures) and the plurality of flow penetrating holes are communicated with the gas source unit 1 and the second chamber room 30, such that the gas source unit 1 provides the process gas to the second chamber room 30 through the plurality of flow penetrating holes on the second flow plate 31. The second heat source 32 is for providing heat conducted to the second chamber room 30 through the second heating plate 33, so as to heat the second chamber room 30 and/or keep temperature of the second chamber room 30, which satisfies demands of the semiconductor process.

It is noted that the first flow plate 21, the first heat source 22, the first heating plate 23, the second flow plate 31, the second heat source 32 and the second heating plate 33 are illustrated as an exemplary embodiment, and structures of the first chamber 2 and the second chamber 3 of the present disclosure are not limited thereto, depending on practical demands.

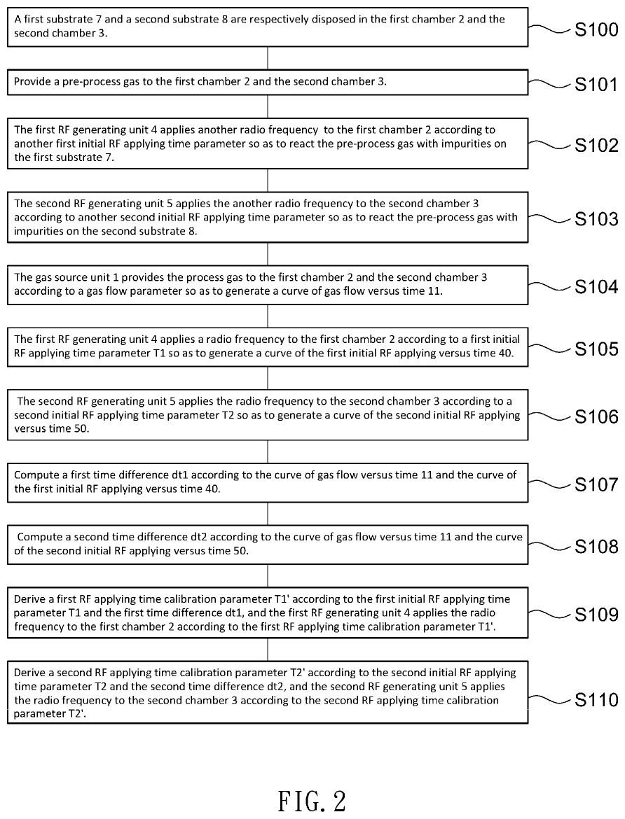

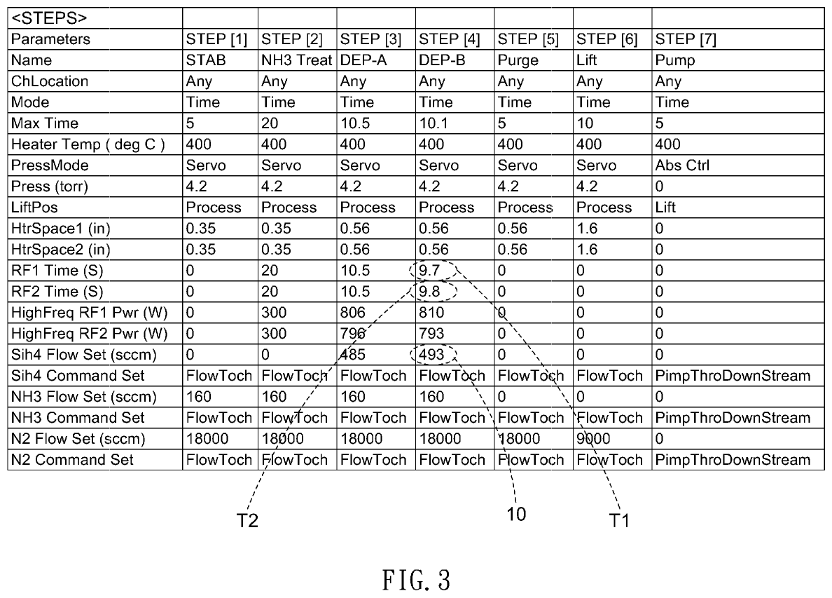

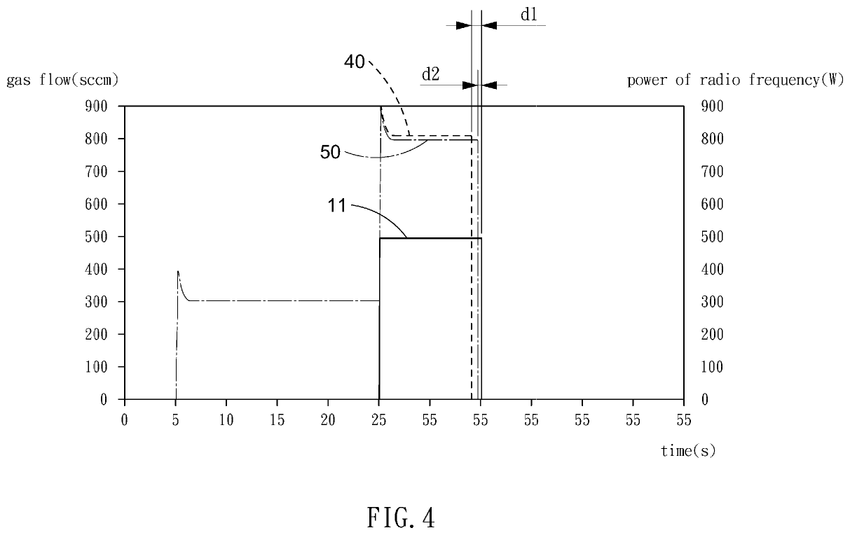

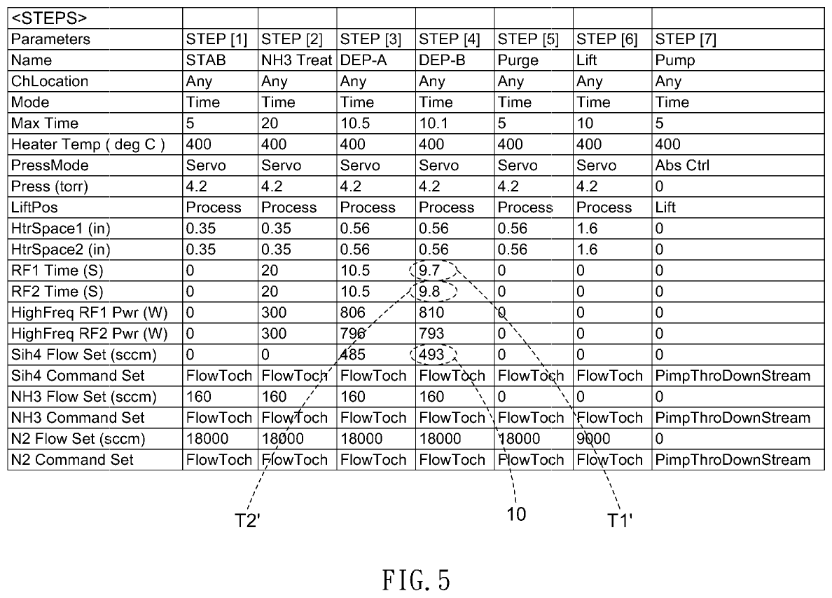

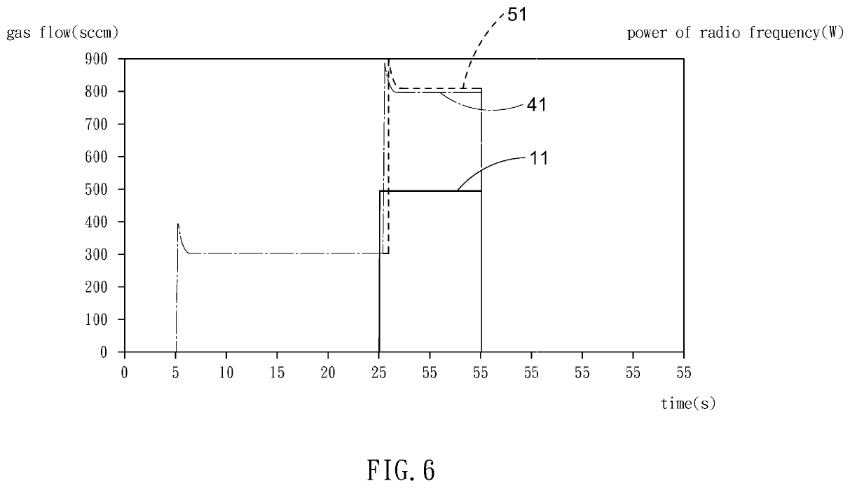

Please refer to FIG. 2 to FIG. 6. FIG. 2 is a flow chart of is a flow chart of the semiconductor process method according to the embodiment of the present disclosure. FIG. 3 shows an example of a user interface table in an initial input status according to the embodiment of the present disclosure. FIG. 4 is a plot diagram of gas flow versus time, showing a plot of the applied first initial RF power versus time and a plot of the applied second initial RF power plot versus time according to the embodiment of the present disclosure. FIG. 5 shows an example of a user interface table in a calibration input status according to the embodiment of the present disclosure. FIG. 6 plot a diagram of gas flow versus time, showing a plot of the applied first calibration RF power versus time and a plot of the applied second calibration RF power plot versus time according to the embodiment of the present disclosure. The semiconductor process method includes following steps of:

Step S100: A first substrate 7 and a second substrate 8 are respectively disposed in the first chamber 2 and the second chamber 3.

Step S101: Provide a pre-process gas to the first chamber 2 and the second chamber 3.

Step S102: The first RF generating unit 4 applies another radio frequency power to the first chamber 2 according to another first initial RF applying time parameter, so as to react the pre-process gas with impurities on the first substrate 7.

Step S103: The second RF generating unit 5 applies the another radio frequency power to the second chamber 3 according to another second initial RF applying time parameter, so as to react the pre-process gas with impurities on the second substrate 8.

Step S104: The gas source unit 1 provides the process gas to the first chamber 2 and the second chamber 3 according to a gas flow parameter, so as to generate a plot of gas flow versus time 11.

Step S105: The first RF generating unit 4 applies a radio frequency power to the first chamber 2 according to a first initial RF applying time parameter T1, so as to generate a plot of the first initial RF applying versus time 40.

Step S106: The second RF generating unit 5 applies the radio frequency power to the second chamber 3 according to a second initial RF applying time parameter T2, so as to generate a plot of the second initial RF applying versus time 50.

Step S107: Compute a first time difference dt1 according to the plot of gas flow versus time 11 and the plot of the first initial RF applying versus time 40.

Step S108: Compute a second time difference dt2 according to the plot of gas flow versus time 11 and the plot of the applied second initial RF power versus time 50.

Step S109: Derive a first RF applying time calibration parameter T1′ according to the first initial RF applying time parameter T1 and the first time difference dt1, and the first RF generating unit 4 applies the radio frequency power to the first chamber 2 according to the first RF applying time calibration parameter T1′.

Step S110: Derive a second RF applying time calibration parameter T2′ according to the second initial RF applying time parameter T2 and the second time difference dt2, and the second RF generating unit 5 applies the radio frequency power to the second chamber 3 according to the second RF applying time calibration parameter T2′.

Detailed description for the semiconductor process method adapted to the multi-chamber apparatus 1000 is provided hereinafter. In Step S100, the first substrate 7 and the second substrate 8 are respectively disposed in the first chamber 2 and the second chamber 3. In the embodiment, the first substrate 7 and the second substrate 8 are made of copper, but the present disclosure is not limited thereto. As mentioned above, the copper-made first substrate 7 and the copper-made second substrate 8 are covered by copper oxide (CuO), which will affect result of subsequent deposition. Thus, in Step S101, the pre-process gas is applied to the first chamber 2 and the second chamber 3. In the embodiment, the pre-process gas is ammonia (NH₃), but the present disclosure is not limited thereto.

In Step S102, the first RF generating unit 4 applies the another radio frequency power to the first chamber 2 according to the another first initial RF applying time parameter, such that the pre-process gas in the first chamber 2 is in a plasma status. Accordingly, the pre-process gas in the plasma status is able to react with impurities (i.e., copper oxide) on the first substrate 7, so as to peel off the impurities on the first substrate 7 from the first substrate 7. Similarly, in Step S103, the second RF generating unit 5 applies the another radio frequency power to the second chamber 3 according to the another second initial RF applying time parameter, such that the pre-process gas in the second chamber 3 is in a plasma status. Accordingly, the pre-process gas in the plasma status is able to react with impurities (i.e., copper oxide) on the second substrate 8, so as to peel off the impurities on the second substrate 8 from the second substrate 8.

After the impurities are peeled off from the first substrate 7 and the impurities are peeled off from the second substrate 8, set the gas source unit 1 to provide the process gas to the first chamber 2 and the second chamber 3 according to the gas flow parameter 10, so as to generate the plot of gas flow versus time 11 (Step S104); set the first RF generating unit 4 to apply the radio frequency power to the first chamber 2 according to the first initial RF applying time parameter T1, so as to generate the plot of the applied first initial RF power versus time 40 (Step S105); and set the second RF generating unit 5 to apply the radio frequency power to the second chamber 3 according to the second initial RF applying time parameter T2, so as to generate the plot of the applied second initial RF power versus time 50 (Step S106). In the embodiment, power of the another frequency is less than power of the radio frequency.

After the plot of gas flow versus time 11, the plot of the applied first initial RF power versus time 40 and the plot of the second initial RF applying versus time 50 are obtained, compute the first time difference dt1 according to the plot of gas flow versus time 11 and the plot of the first initial RF applying versus time 40 (Step S107); and compute the second time difference dt2 according to the plot of gas flow versus time 11 and the plot of the second initial RF applying versus time 50 (Step S108). As shown in FIG. 4, the first time difference dt1 is a difference between a right end value of the plot of gas flow versus time 11 and a right end value of the plot of the first initial RF applying versus time 40, and the second time difference dt2 is a difference between a right end value of the plot of gas flow versus time 11 and a right end value of the plot of the second initial RF applying versus time 50.

After the first time difference dt1 and the second time difference dt2 are obtained, derive the first RF applying time calibration parameter T1′ according to the first initial RF applying time parameter T1 and the first time difference dt1, e.g., the first RF applying time calibration parameter T1′ may be a sum over the first initial RF applying time parameter T1 and the first time difference dt1, and the first RF generating unit 4 applies the radio frequency power to the first chamber 2 according to the first RF applying time calibration parameter T1′ (Step S109); and derive the second RF applying time calibration parameter T2′ according to the second initial RF applying time parameter T2 and the second time difference dt2, e.g., the second RF applying time calibration parameter T2′ may be a sum over the second initial RF applying time parameter T2 and the second time difference dt2; and the second RF generating unit 5 applies the radio frequency power to the second chamber 3 according to the second RF applying time calibration parameter T2′.

As shown in FIG. 5, after the first RF applying time calibration parameter T1′ and the second RF applying time calibration parameter T2′ are implemented, the first RF generating unit 4 applies the radio frequency power to the first chamber 2 according to the first RF applying time calibration parameter T1′, and the second RF generating unit 5 applies the radio frequency power to the second chamber 3 according to the second RF applying time calibration parameter T2′. As shown in FIG. 6, a right end of a plot of first calibration RF applying versus time 41 generated by the first RF generating unit 4 with the first RF applying time calibration parameter T1′ applied to the first chamber 2 coincides a right end of the plot of gas flow versus time 11, and a right end of a plot of second calibration RF applying versus time 51 generated by the second RF generating unit 5 with the second RF applying time calibration parameter T2′ applied to the second chamber 3 coincides a right end of the plot of gas flow versus time 11, i.e., the first RF generating unit 4, the second RF generating unit 5 and the gas source unit 5 of the multi-chamber apparatus 1000 of the present disclosure are turned of simultaneously, such that quality of the first substrate 7 deposited in the first chamber room 20 and the second substrate 8 deposited in the second chamber room 30 are relatively uniform.

As shown in FIG. 1 and FIG. 7, in another embodiment, the multi-chamber apparatus 1000 may further include a first isolated valve A1, a second isolated valve A2 and a clean gas applying unit A3. The first isolated valve A1 and the second isolated valve A2 are coupled to the processor unit C. The clean gas applying unit A3 is selectively communicated with the first chamber room 20 through the first isolated valve A1, and the clean gas applying unit A3 is selectively communicated with the second chamber room 30 through the second isolated valve A2. After the deposition is complete, the processor unit C opens the first isolated valve A1 and the second isolated valve A2, such that the clean gas applying unit A3 is communicated with the first chamber room 20 and the second chamber room 30. In such a manner, clean gas provided by the clean gas applying unit A3 flows into the first chamber room 20 and the second chamber room 30.

In yet another embodiment, the multi-chamber apparatus 1000 may further include a gas discharging unit 9. The gas discharging unit 9 includes an air pump 90, a gas discharging channel 91, a discharging isolated valve 92 and a discharging adjustment valve 93. The gas discharging channel 91 is communicated with the first chamber room 20 and the second chamber room 30. The air pump 90 is selectively communicated with the gas discharging channel 91 through the discharging isolated valve 92 and the discharging adjustment valve 93. When the first isolated valve A1 and the second isolated valve A2 are opened and the clean gas provided by the air pump 90 flows into the first chamber room 20 and the second chamber room 30, the processor unit C opens the discharging isolated valve 92 and the discharging adjustment valve 93, such that the rest gas in the first chamber room 20 and the second chamber room 30 and the clean gas provided by the clean gas applying unit A3 are discharged by the air pump 90 through the gas discharging channel 91.

In again another embodiment, the multi-chamber apparatus 1000 may further include a pressure gauge B1 and a communicating channel B2. The communicating channel B2 is communicated with first chamber room 20 of the first chamber 2 and the second chamber room 30 of the second chamber 3. The pressure gauge B1 is coupled to the first chamber room 20 of the first chamber 2, the second chamber room 30 of the second chamber 3 and the communicating channel B2 and for measuring pressure in first chamber room 20 of the first chamber 2 and the second chamber room 30 of the second chamber 3, so as to keep the pressure in the first chamber 2 and the second chamber 3 during the process.

The above contents are only several embodiments of the present disclosure. For those of ordinary skill in the art, though based on the concepts of the present disclosure, specific implementations and scopes of application may be still subject to change. The content in the specification shall not be deemed limitations.

What is claimed is:

1. A method for semiconductor process, comprising:
generating a first plot of gas flow rate versus time by a gas source unit, wherein the gas source unit provides a process gas to a first chamber and a second chamber according to a gas flow parameter;
generating a plot of an applied first initial RF power versus time, wherein a first RF generating unit applies a radio frequency power to the first chamber according to a first initial RF applying time parameter;
generating a second plot of an applied second initial RF power versus time, wherein a second RF generating unit applies the radio frequency power to the second chamber according to a second initial RF applying time parameter;
computing a first time difference according to the first plot of gas flow rate versus time and the plot of the applied first initial RF power versus time;
computing a second time difference according to the first plot of gas flow versus time and the plot of the applied second initial RF power versus time;
deriving a first RF applying time calibration parameter according to the first initial RF applying time parameter and the first time difference, wherein the first RF generating unit applies the radio frequency power to the first chamber according to the first RF applying time calibration parameter; and
deriving a second RF applying time calibration parameter according to the second initial RF applying time parameter and the second time difference, wherein the second RF generating unit applying the radio frequency power to the second chamber according to the second RF applying time calibration parameter.

2. The method for the semiconductor process of claim 1, further comprising:
disposing a first substrate and a second substrate into the first chamber and the second chamber respectively, before the gas source unit providing the process gas to the first chamber and the second chamber according to the gas flow parameter.

3. The method for the semiconductor process of claim 2, wherein after disposing the first substrate and the second substrate into the first chamber and the second chamber respectively, and before the gas source unit providing the process gas to the first chamber and the second chamber according to the gas flow parameter, the method for semiconductor process further comprises:
providing a pre-process gas to the first chamber and the second chamber respectively;
after providing the pre-process gas to the first chamber and the second chamber, applying another radio frequency power by the first RF generating unit to the first chamber according to another first initial RF applying time parameter so as to react the pre-process gas with impurities on the first substrate; and
after providing the pre-process gas to the first chamber and the second chamber, applying another radio frequency power by the second RF generating unit to the second chamber according to another second initial RF applying time parameter so as to react the pre-process gas with impurities on the second substrate.

4. The method of the semiconductor process of claim 1, further comprising:
after the first RF generating unit applying the radio frequency power to the first chamber according to the first initial RF applying time parameter and after the second RF generating unit applying the radio frequency power to the second chamber according to the second initial RF applying time parameter, discharging the process gas in the first chamber and gas in the second chamber.

5. The method of the semiconductor process of claim 1, further comprising:
communicating the first chamber with the second chamber by a communicating channel; and
measuring a pressure in the first chamber and a pressure in the second chamber by a pressure gauge.

6. A multi-chamber apparatus for a semiconductor process, comprising:
a gas source unit;
a first chamber;
a second chamber,
wherein the gas source unit communicates with the first chamber and the second chamber for providing a process gas to the first chamber and the second chamber;
a first RF generating unit coupled to the first chamber;
a second RF generating unit coupled to the second chamber; and
a processor unit coupled to the gas source unit, the first RF generating unit and the second RF generating unit;
wherein the processor unit is configured to:
control the gas source unit to provide the process gas to the first chamber and the second chamber according to a gas flow parameter, so as to generate a first plot of gas flow versus time;
control the first RF generating unit to apply a radio frequency power to the first chamber according to a first initial RF applying time parameter so as to generate a plot of the first initial RF applying versus time;
control the second RF generating unit to apply a radio frequency power to the second chamber according to a second initial RF applying time parameter so as to generate a plot of the second initial RF applying versus time;
compute a first time difference according to the first plot of gas flow versus time and the plot of the first initial RF applying versus time;
compute a second time difference according to the first plot of gas flow versus time and the plot of the second initial RF applying versus time;
derive a first RF applying time calibration parameter according to the first initial RF applying time parameter and the first time difference, and the first RF generating unit applying the radio frequency power to the first chamber according to the first RF applying time calibration parameter; and
derive a second RF applying time calibration parameter according to the second initial RF applying time parameter and the second time difference, and the second RF generating unit applying the radio frequency power to the second chamber according to the second RF applying time calibration parameter.

7. The multi-chamber apparatus of claim 6, wherein the processor unit is further configured to:
control the gas source unit to provide a pre-process gas to the first chamber and the second chamber, wherein a first substrate and a second substrate are disposed in the first chamber and the second chamber, respectively;
after providing the pre-process gas to the first chamber and the second chamber, control the first RF generating unit to apply another radio frequency power to the first chamber according to another first initial RF applying time parameter so as to react the pre-process gas with impurities on the first substrate; and
control the second RF generating unit to apply the another radio frequency power to the second chamber according to another second initial RF applying time parameter so as to react the pre-process gas with impurities on the second substrate.

8. The multi-chamber apparatus of claim 7, wherein the another radio frequency power is less than the radio frequency power.

9. The multi-chamber apparatus of claim 6, further comprising a gas discharging unit, wherein the gas discharging unit communicates with the first chamber and the second chamber, and wherein the processor unit is further configured to:
after the first RF generating unit applying the radio frequency power to the first chamber according to the first initial RF applying time parameter and after the second RF generating unit applying the radio frequency power to the second chamber according to the second initial RF applying time parameter, control the gas discharging unit to discharge the process gas in the first chamber and the process gas in the second chamber.

10. The multi-chamber apparatus of claim 6, further comprising:
a communicating channel configured to communicate between the first chamber and the second chamber; and
a pressure gauge configured to measure a pressure in the first chamber and a pressure in the second chamber.
